(19) United States
(12) Patent Application Publication
(10) Pub. No.: US 2015/0078735 A1
(43) Pub. Date: Mar. 19, 2015

(54) ELECTRONIC PERSONAL VAPORIZER

(71) Applicant: Cameron Lanning Cormack, Edmonton (CA)

(72) Inventor: Cameron Lanning Cormack, Edmonton (CA)

(21) Appl. No.: 14/028,205

(22) Filed: Sep. 16, 2013

(51) Int. Cl. F28D 21/00; H05K 3/30

(52) U.S. Cl. CPC F28D 21/00; H05K 3/30; F28D 2021/0064
USPC 392/395; 392/394; 29/832

(57) ABSTRACT

An electronic personal vaporizer is provided, having components including a heating element; a liquid container; a power source to provide power to the heating element; a first bulkhead defining an airway at a first end of the vaporizer;

a second bulkhead separating the power source from the heating element and liquid container; and a shell containing the heating element, liquid container and power source. The shell is made of flexible printed circuit and is rolled or folded around the other components to allow for electronic communications to pass along the vaporizer without piercing the bulkheads.

### TECHNICAL FIELD

This invention relates to personal vapour inhaling units and more particularly to electronic personal vaporizers that simulate a cigarette or cigar.

### BACKGROUND OF THE INVENTION

An electronic personal vaporizer is an alternative to smoked tobacco products, such as cigarettes, cigars, or pipes Inhaled doses of vaporized flavour provide a physical sensation similar to smoking. However, because an electronic personal vaporizer typically uses electrical power to atomize a substance, no tobacco, smoke, or combustion is usually involved in its operation. A personal vaporizer may be battery powered for portability and to simulate the physical characteristics of a cigarette, cigar, or pipe. In addition, a personal vaporizer may be loaded with nicotine bearing substance and/or a medication bearing substance. The electronic personal vaporizer may provide an inhaled dose of nicotine and/or medication by way of the atomized and vaporized substance. Thus, personal vaporizers may also be known as electronic cigarettes, e-cigs, electronic cigar, e-cigar, or e-cigarettes. Electronic personal vaporizers may be reusable, with replaceable and refillable components, or may be disposable. Electronic personal vaporizers may be used to administer flavours, medicines, drugs, or any substances that are vaporized and then inhaled.

Typical common components of an electronic personal vaporizer include a light emitting diode, a switch, a battery, liquid cartridge, an atomizer, a tip, and conductors. Typically these components are fitted inside a shell that may resemble the cylindrical appearance of a traditional tobacco cigarette or cigar. The shell is typically a tube made from metal or plastic that approximates the outside diameter and length of a traditional tobacco cigarette or cigar. The shell may also be referred to as a housing, body, tube, enclosure, casing, case, or container. The liquid cartridge is a self-contained structure which typically contains the substance that is to be vaporized. Depending on the design of the electronic personal vaporizer, the cartridge may be coupled to the shell or integral to the shell. Such factors that influence the cartridge design are commonly based on whether or not the electronic personal vaporizer is disposable or reusable, in which case it must be possible to replace or refill the cartridges.

The assembly procedure of the electronic personal vaporizers generally requires delicate human labour since the shell is relatively small in size and the components must be placed inside the shell tube by way of the small open ends. Furthermore many end-caps, seals, bulkheads and components require friction fits to maintain their position inside the shell. Typically the internal components are assembled with human labour prior to their insertion within the shell. Forces manually applied to the internal assembly during insertion to overcome the required friction fits can cause damage to the delicate components and their soldered connections. Additionally, some loose fitting internal components, such as the battery, can also cause damage during shipping and handling of the finished product. The addition of glue to the internal assembly is usually required to prevent unwanted movements of the components.

Bulkheads and seals are employed inside the shell of the electronic personal vaporizer to limit potential contamination of different areas within. One particularly important seal is the bulkhead separating the battery from the atomizer. It is very undesirable to have a damaged battery leak some of its harmful substances into the atomizer area. Although materials exist that can seal well to the shell surface, an inherent problem still exists for this bulkhead. The wires from the battery side of the bulkhead need to pass through to the atomizer. Therefore by nature of current designs, the bulkhead must be breached with apertures for the wires to pass through thus exposing the electronic personal vaporizer to an elevated risk associated with bulkhead leaks.

Currently some mechanical designs are employed which entail complex bulkhead configurations of machined parts, isolators, glands, seals, and sealant to reduce leakage caused from the wire passageways. These current designs create complexity, are costly, and deter current designs from utilizing more wires to pass through the bulkhead for additional functionality.

It is therefore, desirable to have an electronic personal vaporizer and method of fabricating same that: requires less labour to assemble, holds components firmly in position, allows well sealed bulkheads, allows for many wire pathways across bulkheads, allows easy positioning of internal components, and allows for high level of automation in the assembly process.

### SUMMARY OF INVENTION

The present invention overcomes the limitations of the prior art by employing the use of a flexible printed circuit board as the shell of the electronic personal vaporizer. A flexible printed circuit board in its purest form is an array of conductors bonded to a thin dielectric flexible film. Flexible Printed Circuit Boards

(FPCB) can also be referred to as Flex Circuits, flexible printed circuits (FPC), flexible circuitry, and flexible printed circuitry. Most flexible circuits are passive wiring structures that are used to interconnect electronic components such as integrated circuits, resistors, capacitors and the like. The dielectric layer is usually polyimide (PI) or polyester (PET), but other materials can be used such as polyethylene napthalate (PEN), polyetherimide (PEI), paper and other cellulose based materials, along with various fluropolymers (FEP) and copolymers. The circuit can also be easily bonded to a curved surface or formed via elastic and plastic deformation to any shape.

The internal components of an electronic personal vaporizer are interconnected to the FPCB while the FPCB is in a form that allows easy access for this process. After the components are affixed to the FPCB, the FPCB can be deformed into a shape desired for the shell. One embodiment of the present invention is the interconnected FPCB that is elastically deformed into a tubular shell of an electronic personal vaporizer by rolling. The elastic deformation of the FPCB can be stabilized so that it will retain its shape once the external forces that deformed it are removed. The shape stabilization can be achieved by means such as bonding. Bonding of the FPCB can be achieved through chemical, mechanical, or thermal processes. Some means of bonding are achieved through the use of adhesive tapes, stickers, and labels applied to the deformed FPCB to resist the natural spring back movement characteristic of elastic deformation. Additionally, other bonding means can be employed such as melting of the FPCB substrate to itself or other structures. Such thermal bonding operations can be achieved by means of ultrasonic welding, high frequency welding, hot gas welding, friction welding, spin welding, laser welding, contact welding, hot plate welding, and heat sealing to name but a few.

Furthermore the FPCB can also be shaped by plastic deformation thus reducing and possibly eliminating the need for shape stabilization. Plastic deformation of the FPCB can be achieved by exceeding the yield strength of the substrate during deformation. Additionally, the FPCB substrate can be thermally moulded to achieve deformation. Plastic deformation techniques of the FPCB may still require shape stabilization depending on desired characteristics of shape and rigidity of the final deformed shape sought.

Typically the FPCB in its natural form would have a generally flat shape presenting itself more akin to the typical rigid printed circuit board. The components are typically interconnected to the FPCB while in the generally flat shape however deforming particular areas of the naturally shaped FPCB prior to interconnecting may have advantages. Bonding components by way of soldering to the FPCB while it is generally flat will cause the affected areas to remain in its natural shape while deformation of the rest of the FPCB occurs. To overcome this potentially undesirable effect, it would be beneficial to deform the areas where the soldering will be prior to soldering, while leaving a sufficient amount of the FPCB in its natural shape to allow easy access for interconnecting. Once the area is deformed closely to its desired final shape, the components can be soldered to the FPCB thus assuring the shape of the solder bonded area will match to the final overall deformed shape of the FPCB.

There are many structures of FPCB's that could be used in the manner taught by this invention. Some of the FPCB structures include: single-sided, double access or back bared, sculptured, double-sided, multilayer, rigid-flex, and polymer thick film flex circuits. The double-sided and multilayer FPCB structures resolve cross bulkhead wiring issues with the least amount of complexity. A FPCB formed shell for an electronic personal vaporizer can have components on the inside of the shell and on both sides of a bulkhead. In many situations the circuitry of the electronic personal vaporizer may need to interconnect the components across the bulkhead. In this case the conductors printed on the inside of the FPCB, on one side of the bulk head, can pass through the substrate by means of through-holes and vias to connect to conductors printed on the exterior side of the shell. These conductor pathways can then transverse the bulkhead. These pathways, commonly known as traces, can terminate on the outside of the shell or by means of through-holes and vias can pass through the FPCB substrate once again into the interior of the shell where traces can be used to further the conductive pathways. In essence the electrical circuit is bypassing the bulkhead on the exterior of the shell, as to leave the bulkhead intact with no points of penetration through the bulkhead. Since the traces on the exterior are very thin, there is insignificant protrusion of the conductive pathways above the exterior surface of the electronic personal vaporizer shell of the current invention. Furthermore, exterior finishing of the electronic personal vaporizer can further conceal and protect the circuitry present on the exterior surface of the FPCB shell. The bulkhead can be constructed from material compatible with the substrate of the

FPCB and with known bonding technologies. The bulkhead can be bonded with the interior of the FPCB shell by means of adhesives, solvent welding, thermal welding and others. A bulkhead bonded to the FPCB shell that is not breached provides a secure and reliable barrier to keep areas isolated from one another.

Components can be affixed to either side of the FPCB thus allowing switches and Light Emitting Diodes (LEDs) to be soldered to the outside of a formed shell shape as easily as they can be affixed to the inside. Components on the inside of a FPCB shell would generally be affixed before final formation of the FPCB shell. Independently, components on the exterior of a FPCB shell could be affixed prior or after the final formation of the FPCB shell of the present invention.

The switch is a common component of an electronic personal vaporizer. The switch can be used to control the power supplying the atomizer or the switch can signal a controller circuit. There are many types of switches that can be used with the present invention. The membrane switch is a type of switch constructed from FPCB and is both compact and low profile. The membrane switch can be easily integrated into the FPCB shell of an electronic personal vaporizer at marginal cost. There is a minimum amount of FPCB material required to form a shell of a specific shape and size. However, additional material can be allotted in the FPCB which would provide overlap when forming the shell. This overlap could be used for shape stabilization as well as providing the dome element required for a membrane switch.

Furthermore, graphics and artwork can be printed onto the overlapping portion of the FPCB and after finalized formation of the shell; the graphics are viewable as the exterior of the finished form of the FPCB shell. The overlap can be bonded to the FPCB or the FPCB shell can be bound with transparent materials such as tape, plastic wrap, shrink wrap, or plastic tubing to name but a few.

Alternatively the FPCB shell shape can be wrapped with a sticker, label, decal, or tape that has graphics and artwork displayed. This method provides visual elements to the shell as well as provides stabilization to the shell shape.

Furthermore, the FPCB shell can be inserted into other non-FPCB shells or casings. These hard exteriors may have additional electrical components integrated within such as displays, buttons, and controllers to name but a few. The FPCB shell of the present invention can employ electrical contacts on its exterior surface that can couple to electrical contacts on the interior of the more rigid non-FPCB outer shell. The contact coupling allows control of the electrical components inside the FPCB shell via interactions with the outer non-FPCB shell. The non-FPCB outer shell can be comprised of material such as cardboard, plastic, and metal to name but a few.

### BRIEF DESCRIPTION OF THE DRAWINGS

FIG. 1 is an isometric view of seven common internal components found inside a disassembled electronic personal vaporizer.

FIG. 2 is an isometric view of a double sided flexible printed circuit board in a flat orientation.

FIG. 3 is an isometric view of an embodiment of the present invention showing a flexible printed circuit board with common internal components of an electronic personal vaporizer affixed thereon. Some internal hidden features are portrayed.

FIG. 4 is an orthographic top view of an embodiment of the present invention in which hidden features are portrayed with dotted lines.

FIG. 5 is an orthographic view of the proximal end of an embodiment of the present invention.

FIG. 6 is an orthographic view of the proximal end of an embodiment of the present invention. Accompanying this view is also a magnified sectional view of the area denoted with ‘A’.

FIG. 7 is an isometric view of an embodiment of the present invention wherein the bottom of the electronic personal vaporizer is exposed for viewing.

FIG. 8 is an isometric view of an embodiment of the present invention wherein the top of the electronic personal vaporizer is exposed.

FIG. 9 is an orthographic view of the proximal end of an alternate embodiment of the present invention.

FIG. 10 is an isometric view of an alternate embodiment of the present invention. Some internal hidden features are portrayed on the exterior.

FIG. 11 is a view of the top side of an alternative embodiment of the invention,

FIG. 12 is a view of the bottom side thereof.

FIG. 13 is a flowchart demonstrating a method of manufacturing the present invention.

FIG. 14 is an isometric view of an outer casing for use with an embodiment of the invention.

FIG. 15 is an isometric view of an embodiment of the present invention inserted into an outer casing. A partial hidden feature view is provided of the proximal end of the embodiment for visual reference.

### DETAILED DESCRIPTION OF THE EMBODIMENTS

In this document, the following terms will have the following meanings^{.}
a. “stabilize” or “stabilizing” means to make, maintain or hold, firm or steadfast.
b. “shell” means a covering, housing, body, tube, enclosure, casing, case, or container;
c. “electronic personal vaporizer” means a generally cigar or cigarette shaped apparatus designed to allow users to inhale vapour, which may contain a substance, such as nicotine, through one end of the apparatus. Electronic personal vaporizers are also commonly known as electronic cigarettes, e-cigs, electronic cigars, e-cigars, or e-cigarettes.
d. “flexible printed circuit board” or “FPCB” means an array of conductors bonded to a thin dielectric flexible film, and are also referred to as flex circuits, flexible printed circuits (FPCs), flexible circuitry, and flexible printed circuitry.
e. “bond” means to bind, fasten, confine or hold together, and may be by chemical, mechanical or thermal means.
f. “bulkhead” means a partition to prevent the passage of fluid, and may also be referred to as a barrier, hindrance, obstruction, obstacle or baffle.

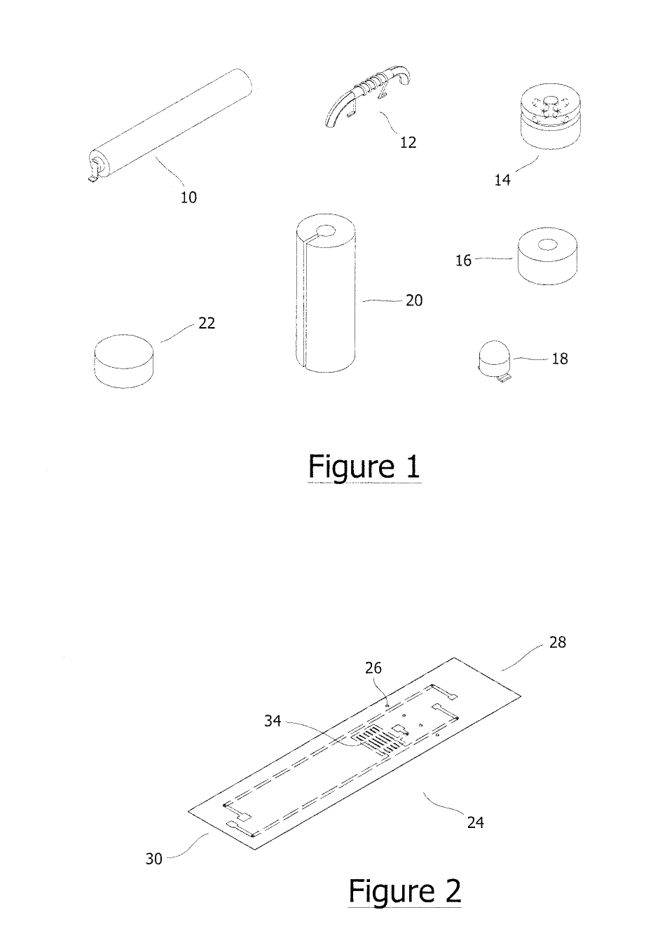

FIG. 1 illustrates common internal components used in the construction of an electronic personal vaporizer. These common components are: a power source, such as a battery (10), an atomizer (12), which may include one or more heating elements, an LED indicator light (18), a liquid container, such as liquid absorbent wadding (20), a bulkhead (14) to separate battery (10) from the atomizer (12) area, an distal end seal bulkhead (22) at the distal end of the vaporizer with respect to the users mouth, and a proximal end seal bulkhead (16) at the proximal end of the vaporizer with respect to the users mouth. Many of these components are electrical, in that they require or provide electrical power. These include the atomizer (12), the LED indicator light (18) and the battery (10).

The absorbent wadding (20) is positioned in contact with the atomizer (12) assembly so as to provide solution that is absorbed in the wadding (20) to the atomizer (12) via a wicking action. The proximal end seal bulkhead (16) has an airway aperture (44) to allow air and vapour to be drawn out of the atomizer area via suction produced by the vaporizer user. Bulkhead (14) has an airway aperture (46) that penetrates axially into the bulkhead but then terminates radially out of the bulkhead. Bulkhead (14) does not have an axial breach.

Referring to FIG. 2, a flexible printed circuit board is shown with electrical traces on the top and bottom sides. This embodiment illustrates a single wrap FPCB (24) configuration. A single wrap FPCB has only enough width of material to be rolled into a single layer around the components. This further means that the axial edges of the FPCB will butt together rather than overlap, as can be seen in detail in FIG. 6. The butting of the axial edges of the FPCB (24) produces a butt seam (32).

Again referring to FIG. 2, various elements can be incorporated into the FPCB such as airway apertures (26) that allow airflow into the atomizer (12) area and a membrane switch contact array (34) which is used to activate the atomizer (12).

The distal end (30) and proximal end (28) of the single wrap FPCB (24) are illustrated for reference. Switch contact array (34) may be an electrical component of the vaporizer.

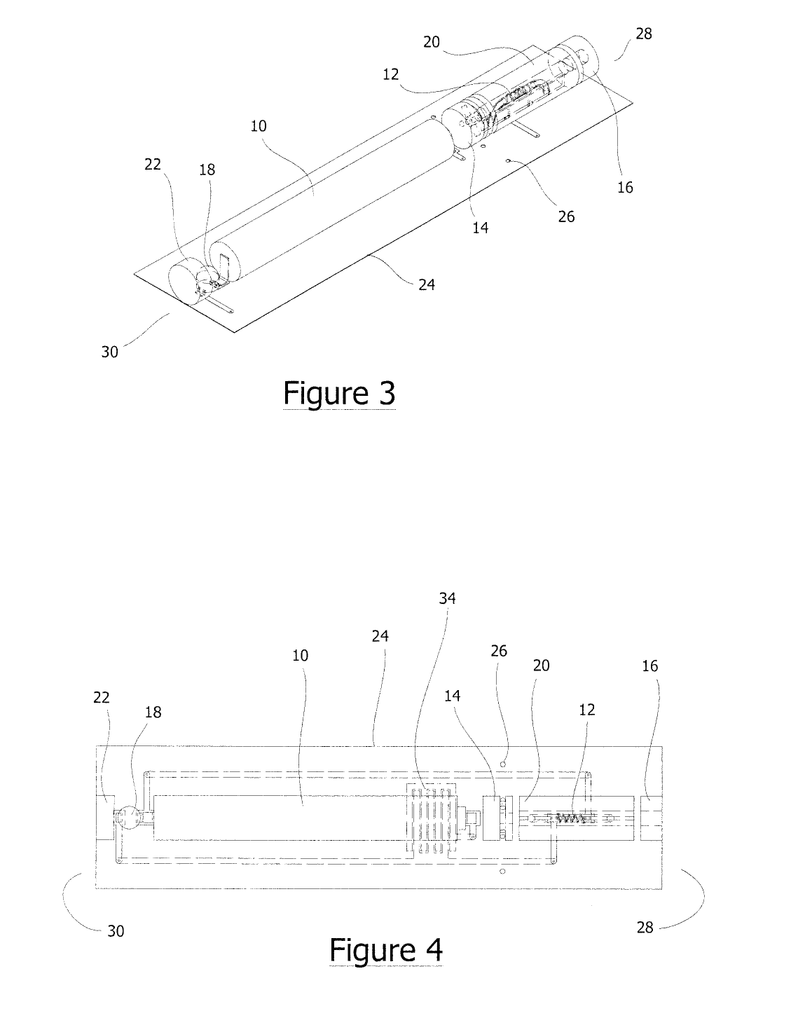

FIG. 3 shows the single wrap FPCB (24) with the common components affixed into position. The components can be easily positioned while the single wrap FPCB (24) is in its natural and flat orientation. The axial portion of airway apertures (46) of the bulkhead (14), absorbent wadding (20), and proximal end seal bulkhead (16) are aligned. Radial portion of airway apertures (46) of the bulkhead (14) are also aligned with the FPCB airway apertures (26).

FIG. 4 shows both traces and components on the top side of the FPCB as well as hidden traces that are on the bottom side of the FPCB. It is apparent that the components are affixed to the FPCB in alignment. This alignment is depicted as an embodiment of the invention but is not required to be in the particular order shown. The components can be affixed in various positions on the FPCB such that the rolling of the single wrap FPCB (24) into a tubular shell will bring the components back into final alignment.

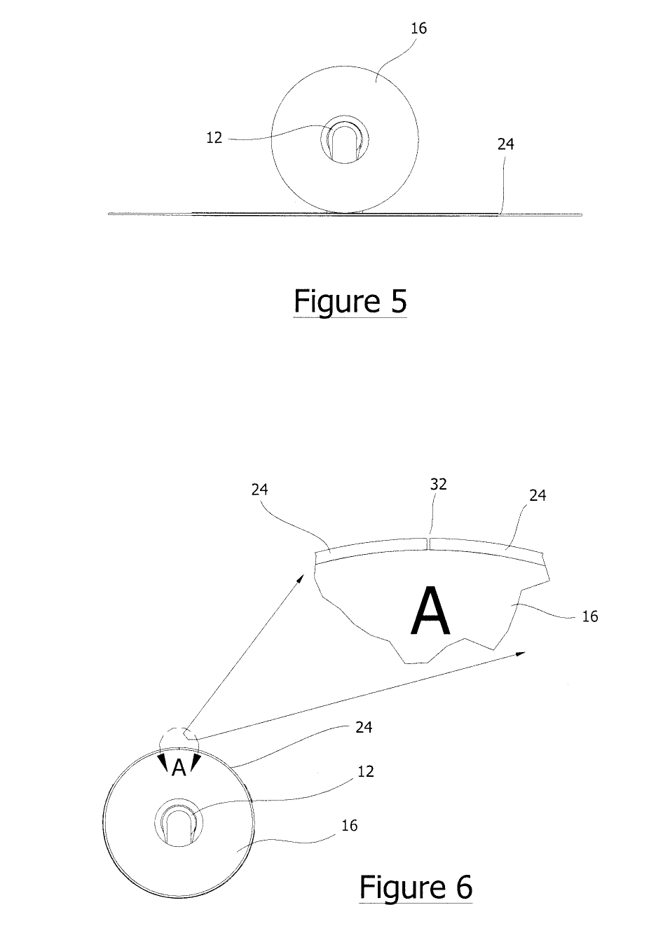

FIG. 5 is a proximal end view of the single wrap FPCB (24) with common components affixed. The atomizer (12) is visible within the airway aperture (44) of the proximal end seal bulkhead (16). The single wrap FPCB (24) can be seen in its natural flat position and provides easy access for component placement.

FIG. 6 is a proximal end view of the single wrap FPCB (24) with common components affixed. The atomizer (12) is visible within the airway aperture (44) of the proximal end seal bulkhead (16). The single wrap FPCB (24) can be seen deformed into a tubular shape around the common components. A magnified view shows the butt seam (32) of the FPCB shell of this embodiment.

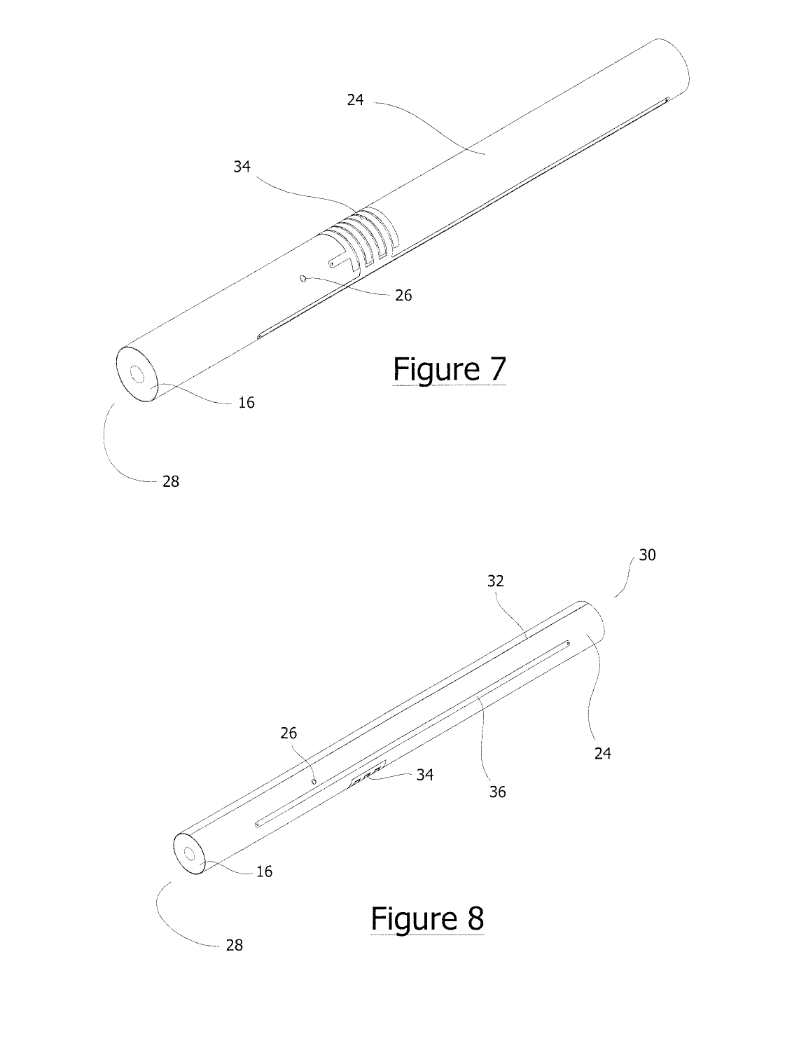

FIG. 7 and FIG. 8 show the single wrap FPCB (24) shell embodiment in an isometric view as to clearly show the features of the shaped shell. FIG. 7 and FIG. 8 show opposite sides of the FPCB shell (24). It can be clearly seen that the top side and bottom side of the single wrap FPCB (24) in its natural orientation become the inside and outside, respectively, of the FPCB (24) shell after it is deformed into a tubular shape. Bulkhead (14) is situated internally between airway apertures (26) and membrane switch contact array (34). The bulkhead (14) does not need to be breached with conductor pathways or passage ways since traces on the inside are connected to traces on the FPCB shell exterior. These radially external traces (36) can transverse the internally located bulkhead (14) thus providing conductive pathways from one side of the cylinder defined by the bulkhead (14) to the other side without breaching the bulkhead (14).

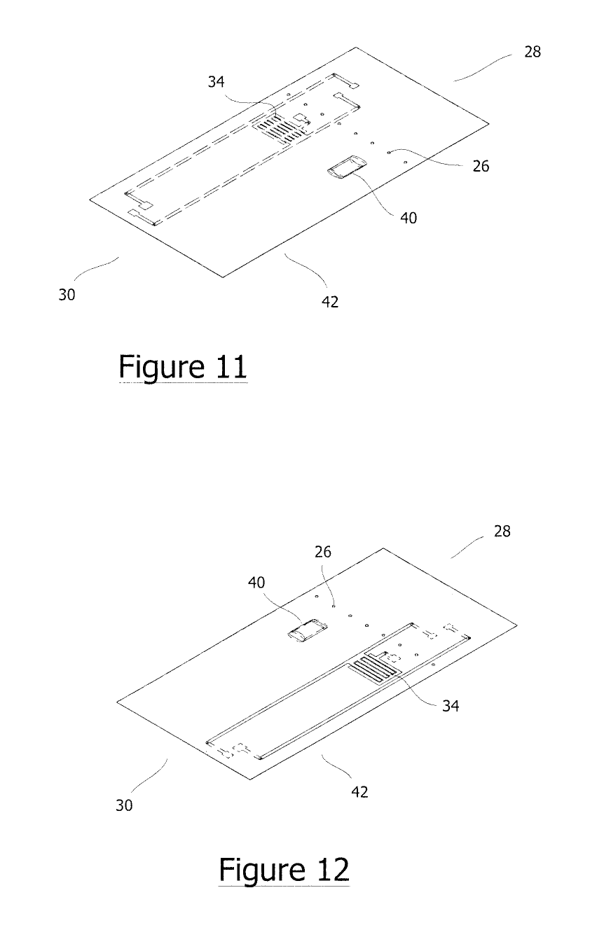

FIG. 11 and FIG. 12 show the top side and bottom side, respectively, of another embodiment of the present invention. A multi-wrap FPCB (42) is shown with integral membrane switch dome (40). The FPCB of the present embodiment has sufficient width to overlap itself when deformed into a tubular shape. The additional FPCB material provides benefits such as improved seam integrity and sealing characteristics, increased shell rigidity, integral graphics, integral membrane switch dome (40), integral shell stabilization means, amongst others.

The conductive surface of the membrane switch dome (40) of FIG. 11 is positioned above the membrane switch contact array (34) of FIG. 12 when the multi-wrap FPCB (42) is deformed by overlapping the a first end (50) of multi wrap FPCB over the second end (52) during wrapping. The alignment of the membrane switch assembly can be seen in FIG. 10. The switch works by pressing the membrane switch dome (40) which contains a conductor on its surface against the membrane switch contact array (34). The dome conductor shorts at least two conductors in the array which then completes a circuit.

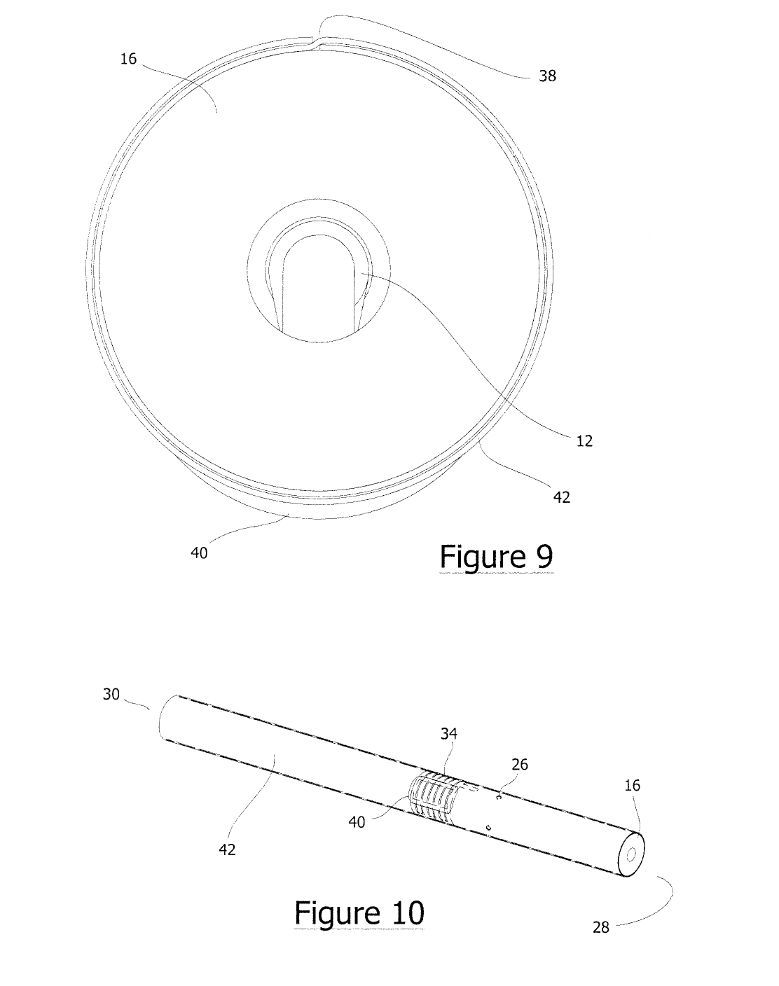

FIG. 9 is a proximal end view of the multi-wrap FPCB (42) with common components affixed. The atomizer (12) is visible within the airway aperture of the proximal end seal bulkhead (16). The multi-wrap FPCB (42) can be seen deformed into a tubular shape around the common components. Also shown is the overlapped butt seam (38) of the FPCB shell of this embodiment. Although this embodiment depicts a FPCB shell comprised of two layers of FPCB material, any number of layers is possible and desired FPCB shell characteristics would be a factor for number of layers. The membrane switch dome (40) can also be seen protruding from the circular FPCB shell body.

The FPCB of these described embodiments would be deformed into tubular shapes via elastic deformation. Therefore there would be a tendency for the FPCB to unwrap and return to its natural orientation once the deformation forces have been removed. Form stabilization means would be required to prevent the FPCB from unwrapping. Such means for the single wrap FPCB (24) and multi-wrap FPCB (42) would be external elements such as stickers, decals, tape, plastic wraps, heat shrink, to name but a few. However the multi-wrap FPCB (42) could additionally be stabilized with adhesives and thermal means applied to the overlapping areas of the FPCB.

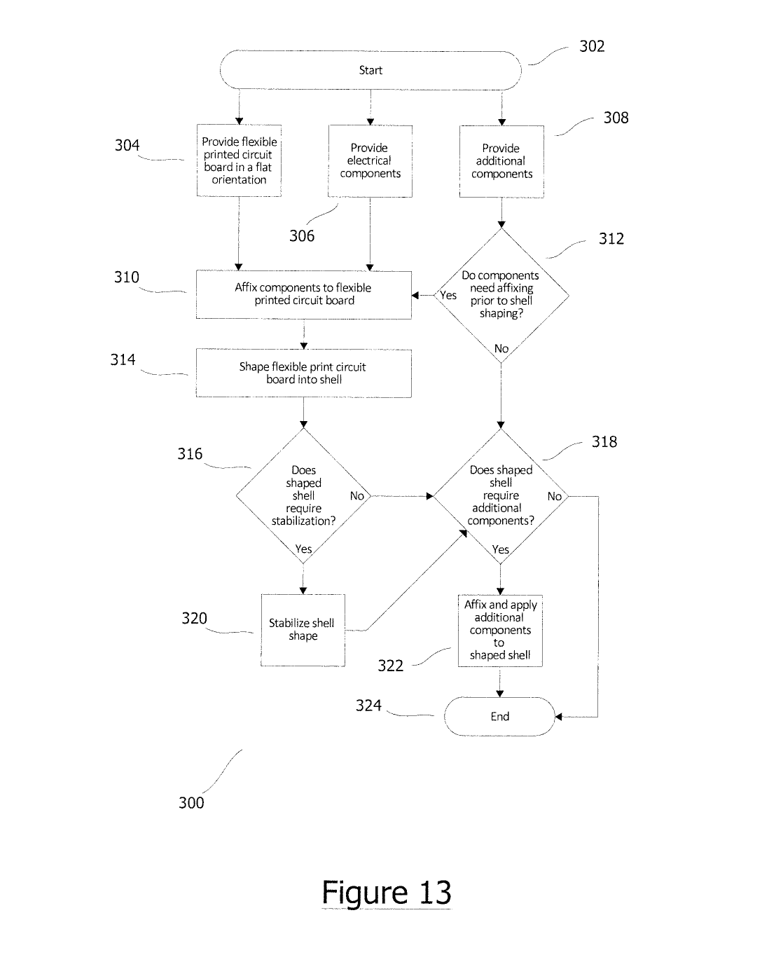

FIG. 13 illustrates an embodiment of a process 300 of manufacturing an electronic personal vaporizer which comprises a FPCB shell. The process begins (step 302) with the provision of a FPCB (step 304), electrical components (step 306) and/or non-electrical components (step 308). According to the manufacturing process described herein at step 312 some components may be affixed prior to deforming (step 310) or after deformation of the FPCB as needed (steps 318 and 322). The FPCB is shaped (step 314) and, if needed at step 316, stabilized (step 320) prior to addition of more components to the shaped shell (step 322). The process is then complete (step 324).

The liquid substance is also a component of the electronic personal vaporizer and may be applied to the device before or afterwards of the shell formation. The preferred method of applying the liquid would be to inject it into the liquid containment area after the FPCB shell is formed. Injecting the liquid afterwards minimizes the contamination of liquid into the automated assembly equipment and FPCB shell surfaces prior to forming and stabilizing.

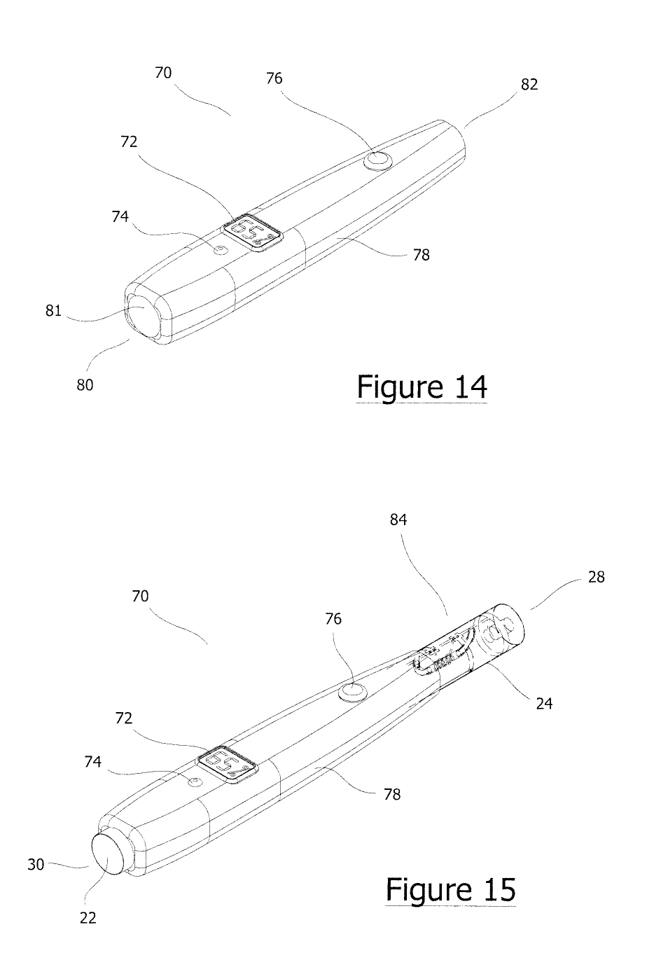

As shown in FIGS. 13 and 14, FPCB shell (24) can be inserted into and affixed to non-FPCB shells or casings (70). FIG. 15 display a portion (84) of the personal vaporizer that would normally be hidden from view. Casing (70) may have additional electrical components integrated within such as display (72), button (74), and controller (76) to name but a few. Display (72) can be configured to display any sort of information, for example battery level, power output level, runtime, dose, time, date, etc. Display (72) can be a LCD, LED or other type of display. Button (74) is used to control display (72) and make selections from menus and options that may be displayed.

The FPCB shell (24) can employ electrical contacts on its exterior surface that couple to electrical contacts on the interior of casing (70). The contact coupling allows control of the electrical components inside the FPCB shell (24) via interactions with the outer non-FPCB casing (70). Casing (70) can be comprised of material such as cardboard, wood, paper, plastic, and metal to name but a few. Controller (76) is operatively coupled to FPCB shell (24) to actuate the vaporizer.

Casing (70) has an outer side (78), a distal end (80) and proximal end (82). FPCB (24) can be inserted into casing (70) through aperture (81). In alternative embodiment of the invention, aperture (81) may not extend the length of casing (70), for example two or more casings could be used to envelop FPCB (24), or casing (70) may only partially cover FPCB (24).

Casing (70) can be of any configuration or shape, the embodiment shown represents a typical casing (70). Multi-wrap FPCB (42) could be used in place of single wrap FPCB (24).

The above-described embodiments have been provided as examples, for clarity in understanding the invention. A person with skill in the art will recognize that alterations, modifications and variations may be effected to the embodiments described above while remaining within the scope of the invention as defined by claims appended hereto. As examples, liquid absorbent wadding (20) is shown in the embodiment as a representative of a liquid container for providing liquid to a heating element for vaporization. As a further example the FPCB can be deformed into a shape appropriate for a pipe shaped electronic personal vaporizer.

I claim:

1. An electronic personal vaporizer, comprising:
a. a plurality of electrical components; and
b. a shell comprising a flexible printed circuit board; and
wherein the flexible printed circuit board operatively couples the electrical components.

2. The electronic personal vaporizer of claim 1 wherein the electrical components include a power source.

3. The electronic personal vaporizer of claim 1 wherein the electrical components include an atomizer.

4. The electronic personal vaporizer of claim 1 wherein the electrical components include a switch.

5. The electronic personal vaporizer of claim 1 further comprising liquid for atomizing.

6. The electronic personal vaporizer of claim 1 further comprising a plurality of non-electrical components.

7. The electronic personal vaporizer of claim 1 wherein the shell is tubular in shape.

8. The electronic personal vaporizer of claim 2 wherein the electrical components include a liquid atomizer and the vaporizer further comprising:
a. liquid for atomizing; and
b. a first bulkhead defining an airway at a first end of the vaporizer.

9. The electronic personal vaporizer of claim 5 wherein the liquid for atomizing is entrained in an absorbent wadding.

10. The electronic personal vaporizer of claim 8 further comprising a second bulkhead separating the power source for the liquid atomizer from the liquid and liquid atomizer.

11. The electronic personal vaporizer of claim 1 wherein the shell is positioned within an external housing.

12. The electronic personal vaporizer of claim 11 wherein the external housing is made of plastic.

13. The electronic personal vaporizer of claim 11 wherein the external housing is made of wood.

14. The electronic personal vaporizer of claim 11 wherein the external housing is made of cardboard.

15. The electronic personal vaporizer of claim 11 wherein the external housing is made of paper.

16. The electronic personal vaporizer of claim 11 wherein the external housing is made of metal.

17. The electronic personal vaporizer of claim 11 wherein the external housing is tubular in shape.

18. The electronic personal vaporizer of claim 11 wherein the external housing is operatively coupled to the shell.

19. The electronic personal vaporizer of claim 3 wherein the liquid atomizer comprises a heating element.

20. A method of manufacturing an electronic personal vaporizer, comprising the steps of:
a. providing a plurality of components of the vaporizer, including a plurality of electrical components;
b. providing a flexible printed circuit board to serve as a shell for the vaporizer; and
c. shaping the flexible printed circuit board around the components to operatively couple the plurality of electrical components.

21. The method of claim 20 wherein the shell is shaped by rolling the flexible printed circuit board into a tube around the components.

22. The method of claim 20 wherein the shell is shaped by folding the flexible printed circuit board around the components.

23. The method of claim 20 wherein the shell is shaped by:
a. affixing the components to the flexible printed circuit board in a flattened state,
b. shaping the flexible printed circuit board into a shape; and
c. stabilizing the flexible printed circuit board in the shape.

24. The method of claim 23 wherein the flexible printed circuit board is stabilized by use of an adhesive.

25. The method of claim 23 wherein the flexible printed circuit board is stabilized by use of tape.

26. The method of claim 23 wherein the flexible printed circuit board is stabilized by use of fasteners.

27. The method of claim 23 wherein the flexible printed circuit board is stabilized by use of heat melting.

28. The method of claim 21 wherein the flexible printed circuit board has a first end and a second end, and when the flexible printed circuit board is rolled around the components, the first end and the second end meet at and are sealed at a butt joint.

29. The method of claim 21 wherein the flexible printed circuit board has a first end and a second end, and when the flexible printed circuit board is rolled around the components, the second end overlaps the first end.

30. An electronic personal vaporizer, comprising:
a. a plurality of components including a power source and means for vaporizing a liquid;
b. means for containing the components in position within the vaporizer; the means for containing the components operatively coupling the power source and the means for vaporizing the liquid.

31. The electronic vaporizer of claim 30 further comprising means for actuating the means for vaporizing a liquid, the means for actuating operatively coupled to the means for containing the components.

32. The electronic vaporizer of claim 31 wherein the means for actuating is a switch.

33. The electronic vaporizer of claim 32 further comprising means for storing the liquid within the means for containing the components.
